(19) United States
(12) Patent Application Publication
(10) Pub. No.: US 2025/0125173 A1
(43) Pub. Date: Apr. 17, 2025

(54) Calibration Method and Substrate Processing System

(71) Applicant: Tokyo Electron Limited, Tokyo (JP)

(72) Inventors: Toshiaki KODAMA, Yamahashi (JP); Takumi HIRANO, Yamahashi (JP)

(21) Appl. No.: 18/905,097

(22) Filed: Oct. 2, 2024

(30) Foreign Application Priority Data
Oct. 12, 2023 (JP) 2023-176994

(51) Int. Cl. H01L 21/67; H01L 21/677; H01L 21/68; H01L 21/687

(52) U.S. Cl. CPC H01L 21/67259; H01L 21/67706; H01L 21/681; H01L 21/68707

(57) ABSTRACT

Provided is a calibration method for calibrating a sensor in a system including a transfer device for transferring an object, and the sensor for detecting the object to recognize a position of the object that is being transferred by the transfer device, the method comprising: (A) placing the object on a support part configured to support the object such that a center position of the object is located within an allowable range from a center position of the support part; and (B) after said (A), holding and transferring the object placed on the support part by the transfer device, detecting the object that is being transferred by the sensor, and calibrating the position of the object detected by the sensor.

### CROSS-REFERENCE TO RELATED APPLICATIONS

This application claims priority to Japanese Patent Application No. 2023-176994 filed on Oct. 12, 2023, the entire contents of which are incorporated herein by reference.

### TECHNICAL FIELD

The present disclosure relates to a calibration method and a substrate processing system.

### BACKGROUND

Japanese Patent Publication No. 6656200 discloses a substrate processing system for transferring a substrate from a vacuum transfer module (transfer module) to a process module and performs substrate processing such as plasma processing on the substrate. The substrate processing system of Japanese Patent Publication No. 6656200 detects the position (positional relationship between the substrate and a focus ring) of the substrate placed on a placing table of the process module using a transfer device and a position detection system of an optical system, and determines deviation of the substrate with respect to the placing table.

Such a substrate processing system may include a sensor at or near a loading/unloading port of the process module, and may be configured to detect the substrate transferred by the transfer device using the sensor and recognize the position of the substrate. The substrate processing system can suppress the deviation of the substrate with respect to the placing table of the process module by correcting the transfer position of the substrate transferred by the transfer device based on the detection result of the sensor.

### SUMMARY

The present disclosure provides a technique capable of improving transfer accuracy of a transfer object.

In accordance with an aspect of the present disclosure, there is provided a calibration method for calibrating a sensor in a system including a transfer device for transferring an object, and the sensor for detecting the object to recognize a position of the object that is being transferred by the transfer device, the method comprising: (A) placing the object on a support part configured to support the object such that a center position of the object is located within an allowable range from a center position of the support part; and (B) after said (A), holding and transferring the object placed on the support part by the transfer device, detecting the object that is being transferred by the sensor, and calibrating the position of the object detected by the sensor.

### BRIEF DESCRIPTION OF THE DRAWINGS

FIG. 1 is a schematic plan view showing an example of an overall configuration of a substrate processing system according to an embodiment.

FIG. 2 is an enlarged plan view showing a substrate and a fork of a vacuum transfer device.

FIG. 3 is a cross-sectional view schematically showing a processing module.

FIG. 4 is an enlarged cross-sectional view showing a state in which a substrate and a ring are placed on a substrate support.

FIG. 5A is a side view explaining principle of teaching a transfer position of a vacuum transfer device.

FIG. 5B is a plan view explaining the principle of teaching the transfer position of the vacuum transfer device.

FIG. 5C is a side view showing an operation during calibration of a processing module-side sensor.

FIG. 6A is a flowchart showing a calibration method according to an embodiment.

FIG. 6B is a flowchart showing a transfer teaching step of the calibration method.

FIG. 7 is a flowchart specifically illustrating operations of individual components in the transfer teaching step.

FIG. 8A is a cross-sectional view showing a detection operation of the ring and the substrate support in a first detection step.

FIG. 8B is a cross-sectional view showing a detection operation of the ring and the substrate in a second detection step.

### DETAILED DESCRIPTION

Hereinafter, embodiments of the present disclosure will be described in detail with reference to the accompanying drawings. Like reference numerals will be given to like parts throughout the drawings, and redundant description thereof may be omitted.

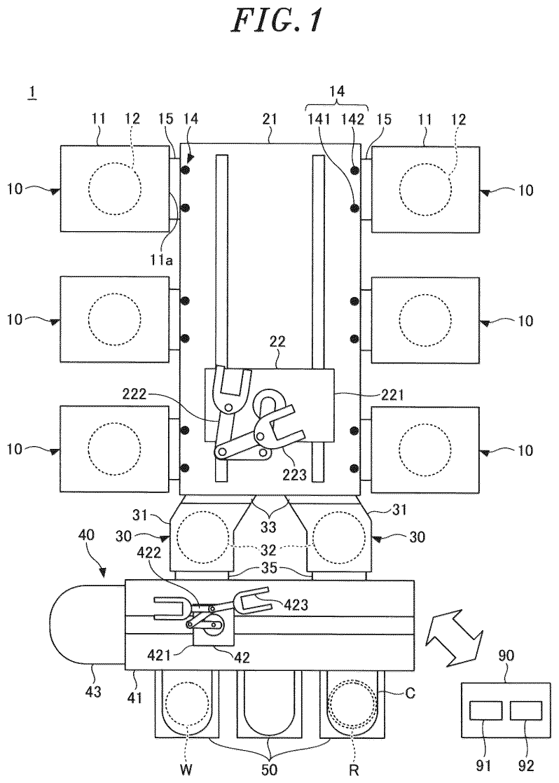

FIG. 1 is a schematic plan view showing an example of an overall configuration of a substrate processing system 1 according to an embodiment. As shown in FIG. 1, the substrate processing system 1 is a multi-chamber type semiconductor manufacturing device including multiple (six) processing modules 10. Each processing module 10 performs substrate processing such as film formation, etching, cleaning or the like on a substrate W transferred thereinto. The substrate processing system 1 further includes, in addition to the processing modules 10, a vacuum transfer module 20, multiple load-lock modules 30, an atmospheric transfer module 40, a load port 50, and a controller 90.

The substrate W is loaded and unloaded between each processing module 10 and the vacuum transfer module 20. Each processing module 10 performs the substrate processing on the substrate W loaded thereinto. The number of processing modules 10 disposed in the substrate processing system 1 is not particularly limited. The multiple processing modules 10 may perform the same processing. Alternatively, some of them or all of them may perform different types of processing. The substrate processing system 1 may be configured to perform plasma processing in some or all of the processing modules 10.

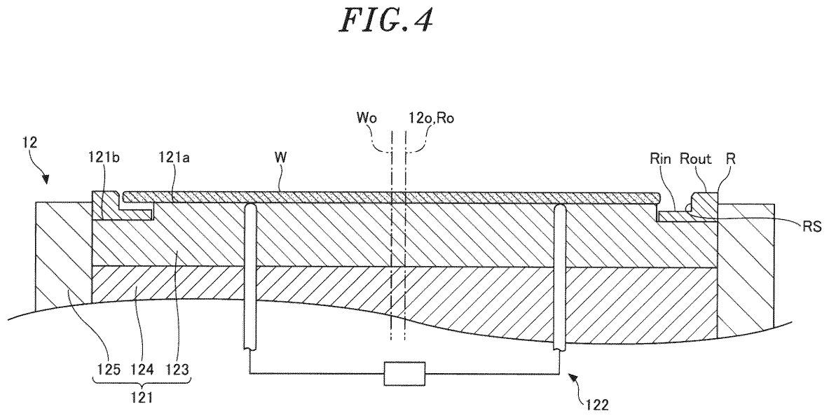

Each processing module 10 has a processing chamber 11 accommodating a substrate W, and a substrate support 12 on which the substrate W is placed in the processing chamber 11. The substrate support 12 is provided with lifters 122 (e.g., multiple pins: see FIG. 4) for raising and lowering the substrate W, and receives and delivers the substrate W in cooperation with a vacuum transfer device 22 of a vacuum transfer module 20 to be described later. Among the processing modules 10, the processing module 10 for performing plasma processing will be described in detail later.

Further, the substrate processing system 1 has connection parts 15 that connect the processing chambers 11 of the processing modules 10 and the vacuum transfer module 20, and processing module-side sensors 14 for detecting the substrate W. The connection part 15 has therein a gate valve (not shown) for opening and closing an opening 11a of the processing chamber 11. In each processing module 10, the substrate W can be transferred to the processing chamber 11 via the connection part 15 by opening the gate valve, and the pressure in the processing chamber 11 can be reduced to an appropriate vacuum atmosphere by closing the gate valve.

The processing module-side sensor 14 detects the outer edge of the substrate W when the substrate W is transferred between each processing module 10 and the vacuum transfer module 20, and transmits the detection information to the controller 90. The controller 90 can calculate the center position of the substrate W based on the detection information of each processing module-side sensor 14, and can also recognize the deviation of the center position of the substrate W that is being transferred to the vacuum transfer device 22. The processing module-side sensor 14 is disposed at a position adjacent to the opening 11a of each processing module 10 in the vacuum transfer module 20, for example. The processing module-side sensor 14 may be disposed in the connection part 15, or may be disposed at a position adjacent to the opening 11a in the processing module 10.

The processing module-side sensor 14 has two detectors 141 and 142 for detecting whether or not the substrate W exists. For example, each of the detectors 141 and 142 includes a light emitting part (not shown) for emitting light for measurement and a light receiving part (not shown) for receiving light from the light emitting portion with a route through which the substrate W passes interposed therebetween. The detectors 141 and 142 detect the presence of the substrate W when the light for measurement is blocked by the passage of the substrate W. The two detectors 141 and 142 are arranged in a direction parallel to the opening 11a, and they are arranged such that the distance therebetween becomes shorter than the diameter of the substrate W. The principle in which the position of the substrate W is calculated by the detection by the processing module-side sensor 14 is the same as that of fork-side sensors 227 of the vacuum transfer device 22 to be described later, and will be described in detail later.

The vacuum transfer module 20 of the substrate processing system 1 includes a transfer chamber 21 connected to the respective processing modules 10 and the respective load-lock modules 30, and a vacuum transfer device 22 for transferring the substrate W disposed in the transfer chamber 21. The vacuum transfer module 20 may include multiple transfer regions (or transfer chambers 21) each having the vacuum transfer device 22 and a path region that connects the transfer regions, and may be configured to transfer the substrate W from one transfer region to another transfer region via the path region.

The transfer chamber 21 is formed in a rectangular shape in plan view, and has a transfer space 21s that is airtightly sealed from the outside. The transfer space 21s is depressurized to a vacuum atmosphere by a vacuum suction device (not shown). In the substrate processing system 1 according to the embodiment, three processing modules 10 are connected to each of a pair of long sides of the transfer chamber 21. Further, the substrate processing system 1 has two load-lock modules 30 connected to one short side of the transfer chamber 21.

The vacuum transfer device 22 moves in the transfer space 21s under the control of the controller 90 to transfer the substrate W. For example, the vacuum transfer device 22 transfers the substrate W from an appropriate load-lock module 30 to an appropriate processing module 10. Further, the vacuum transfer device 22 transfers the substrate W from an appropriate processing module 10 to an appropriate load-lock module 30 under the control of the controller 90. The vacuum transfer device 22 may transfer the substrate W between two processing modules 10. The transfer object transferred by the vacuum transfer device 22 is not limited to the substrate W. For example, when a ring R, which will be described later and is applied to the processing module 10, is transferred via the vacuum transfer module 20 and set in the processing module 10, the transfer object transferred by the vacuum transfer device 22 may include the ring R.

The vacuum transfer device 22 has a base 221 that is movable in the longitudinal direction of the transfer chamber 21, multiple arms 222 that can rotate, extend and contracting, and move up and down with respect to the base 221, and a fork (end effector) 223 disposed at the arm 222 on the distal end side. Although FIG. 1 illustrates an example of the vacuum transfer device 22 having two forks 223, the vacuum transfer device 22 may have one or three or more forks 223.

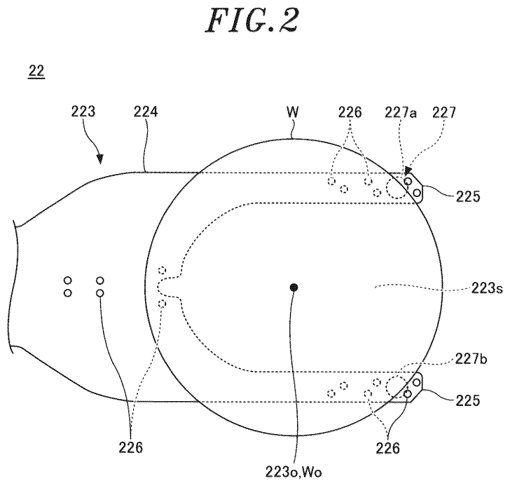

FIG. 2 is an enlarged plan view of the substrate W and the forks 223 of the vacuum transfer device 22. As shown in FIG. 2, the vacuum transfer device 22 supports the substrate W on the upper surface of the forks 223, and transfers the substrate W by appropriately operating the base 221 and the arms 222 shown in FIG. 1.

The fork 223 has a base plate portion 224 connected to the arm 222 at the distal end side, and a pair of support plate portions 225 extending while being branched from the base plate portion 224. The base plate portion 224 and the pair of support plate portions 225 are integrally molded with each other and continuous in the horizontal direction, thereby forming a U-shape in plan view. The pair of support plate portions 225 are parallel to each other, and have the same length. The fork 223 has a concave space 223s surrounded by the base plate portion 224 and the pair of support plate portions 225. The concave space 223s is opened at the tip ends (extension ends) of the pair of support plate portions 225.

Further, the fork 223 has a plurality of pads 226 on the upper surfaces of the base plate portion 224 and the support plate portions 225. For example, the plurality of pads 226 are disposed at intermediate positions in the width direction of the base plate portion 224, and are also disposed on the tip end sides of the pair of support plate portions 225 to directly support the positions of the substrate W in three directions. The plurality of pads 226 may be made of a material (such as an elastomer or the like) having appropriate frictional force and elasticity. Further, the fork 223 may have a holding device such as a suction mechanism, an electrostatic attraction mechanism, or a mechanical locking mechanism for holding the substrate W using the plurality of pads 226 (or instead of the plurality of pads 226).

In the case of supporting the substrate W with the fork 223, the vacuum transfer device 22 moves the fork 223 such that a center position Wo of the substrate W coincides with a reference position 2230 that is preset at the fork 223. The position where the fork 223 of the vacuum transfer device 22 moves to place or receive the substrate W corresponds to “transfer position” in the embodiment. The vacuum transfer device 22 moves the fork 223 such that the reference position 2230 coincides with the transfer position specified by the control. Accordingly, the substrate W can be supported such that the reference position 2230 of the fork 223 coincides with the center position Wo of the substrate W, and the supported substrate W can be aligned with the transfer position.

The fork 223 has the fork-side sensors 227 for detecting the substrate W as a transfer object on the surface (bottom surface) opposite to the surface for supporting the substrate W. The fork-side sensors 227 according to the embodiment have multiple (two in FIG. 2) detectors 227a and 227b. Each of the detectors 227a and 227b is disposed near the extension ends (tip ends of the fork 223) of the pair of support plate portions 225, and detects an object disposed below (opposed to) the fork 223 in the vertical direction. Each fork-side sensor 227 is connected to the controller 90 to be communicable therewith, performs detection under the control of the controller 90, and transmits the detection information to the controller 90.

For example, the fork-side sensor 227 may be a displacement sensor for optically measuring the distance from the fork 223 to the object. In this case, each of the detectors 227a and 227b of the fork-side sensors 227 has a light emitting part and a light receiving part, and measures the distance to the object based on the light intensity or wavelength of the detection light emitted by the light emitting part and reflected by the object. Further, each of the detectors 227a and 227b may be configured to detect a change in the height of the object by an on/off signal. For example, when the detection of the fork-side sensors 227 is continued while the fork 223 is moving above the substrate W, the fork-side sensors 227 can detect a change in the height at the outer edge of the substrate W, and the controller 90 can recognize the position of the outer edge of the substrate W based on the detection information. The controller 90 can calculate the center position of the substrate W using the detected multiple locations on the outer edge of the substrate W by a calculation method to be described below.

The type of the fork-side sensors 227 is not particularly limited as long as the substrate processing system 1 can acquire the center position of the substrate W to be transferred. The fork-side sensor 227 may also be an on-off sensor that detects the outer edge of the substrate W by transmitting or blocking of detection light, a capacitance sensor that detects a change in a capacitance when it passes through a position above the substrate W, or the like. Alternatively, the fork-side sensor 227 may be an infrared sensor, an ultrasonic sensor, a radar, a camera, or the like. Further, in the substrate processing system 1, the position and number of the fork-side sensors 227 or the number of detectors are not particularly limited. For example, if one camera is applied to the fork-side sensor 227 and images a part of the outer edge of the substrate W, it is possible to calculate the center position of the substrate W.

Referring back to FIG. 1, the two load-lock modules 30 of the substrate processing system 1 are disposed between the vacuum transfer module 20 and the atmospheric transfer module 40, and an inner atmosphere thereof is switched between an atmospheric atmosphere and a vacuum atmosphere. Specifically, each load-lock module 30 includes a chamber 31 accommodating the substrate W, and a placing table 32 for placing the substrate W thereon in the chamber 31. For example, the placing table 32 has a groove (not shown) into which the fork 223 of the vacuum transfer device 22 and the fork 423 of the atmospheric transfer device 42 (to be described later) can enter, and the substrate W is received and delivered by moving the forks 223 and 423 back and forth and up and down. The placing table 32 may include lifters, similarly to the substrate support 12 of the processing module 10.

Each load-lock module 30 includes a connection part 33 on the vacuum transfer module 20 side and a connection part 35 on the atmospheric transfer module 40 side. The connection parts 33 and 35 have therein gate valves (not shown) for opening and closing the opening of the chamber 31. Each load-lock module 30 communicates with the vacuum transfer module 20 by opening the gate valve of the connection part 33 in a vacuum atmosphere. Each load-lock module 30 communicates with the atmospheric transfer module 40 by opening the gate valve of the connection part 35 in an atmospheric state.

The inner atmosphere of the atmospheric transfer module 40 of the substrate processing system 1 is maintained in an atmospheric atmosphere. The atmospheric transfer module 40 includes a transfer chamber 41 connected to the load-lock modules 30 and an atmospheric transfer device 42 for transferring the substrate W in the transfer chamber 41. In the atmospheric transfer module 40, downflow of clean air may be generated in the transfer chamber 41. In addition, an aligner 43 for aligning the substrate W is disposed on the lateral side of the atmospheric transfer module 40.

Further, the plurality of load ports 50 are provided on the wall surface of the atmospheric transfer module 40. A carrier C containing a substrate W or an empty carrier C is attached to each load port 50. The carrier C may be, e.g., a front opening unified pod (FOUP) or the like. The carrier C accommodating the ring R (a focus ring, an edge ring, or the like) that is an example of a transfer object may be attached to each load port 50. The ring R is disposed around the substrate W on the substrate support 12 of the processing module 10.

Similar to the vacuum transfer device 22, the atmospheric transfer device 42 includes a base 421 that is movable in the longitudinal direction of the transfer chamber 41, a plurality of arms 422 that can rotate, extend and contract, and move up and down with respect to the base 421, and a fork (end effector) 423 disposed at the arm 422 on the distal end side. The atmospheric transfer device 42 supports the substrate W on the upper surface of the fork 423, and transfers the substrate W by appropriately operating the base 421 and the arms 422. Although FIG. 1 illustrates the atmospheric transfer device 42 including two forks 423, the present disclosure is not limited thereto, and the atmospheric transfer device 42 may have a configuration including one or three or more forks 423.

The atmospheric transfer device 42 transfers the substrate W between each load-lock module 30 and the atmospheric transfer module 40 by opening and closing the gate valve of each connection part 35. Further, the atmospheric transfer device 42 transfers the substrate W between the aligner 43 and the atmospheric transfer module 40. Further, the atmospheric transfer device 42 transfers the substrate W between each carrier C attached to each load port 50 and the atmospheric transfer module 40.

The controller 90 is a computer including a processor 91, a memory 92, an input/output interface, and a communication interface (not shown). The processor 91 is combination of one or more of a central processing unit (CPU), a graphics processing unit (GPU), an application specific integrated circuit (ASIC), a field-programmable gate array (FPGA), a circuit including a plurality of discrete semiconductors, and the like, and executes the program stored in the memory 92. The memory 92 includes a main storage device such as a semiconductor memory, and an auxiliary storage device such as a disk, a drive, a semiconductor memory (flash memory), or the like.

For example, the controller 90 controls the atmospheric transfer device 42 to transfer an unprocessed substrate W of the carrier C attached to the load port 50 to the aligner 43 so that the substrate W can be aligned, and to transfer the substrate W of the aligner 43 to one of the load-lock modules 30. After the load-lock module 30 containing the substrate W is depressurized, the controller 90 controls the vacuum transfer device 22 to take out the substrate W and transfers the substrate W to one of the processing modules 10 via the vacuum transfer module 20. Thereafter, the controller 90 performs substrate processing in each processing module 10 into which the substrate W is loaded. After the substrate processing, the controller 90 transfers the substrate W of one processing module 10 to the carrier C for accommodating a processed substrate W in a reverse order of the above-described sequence.

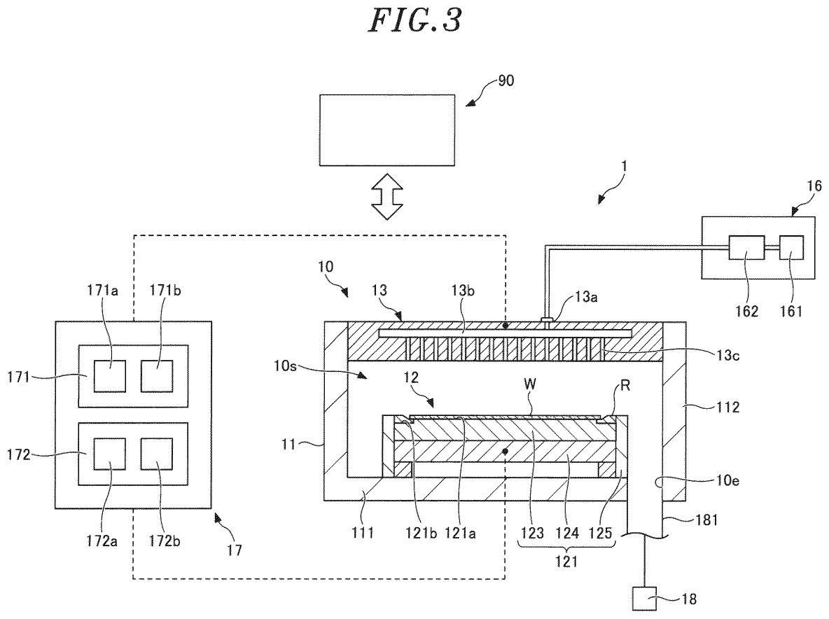

Next, an example of the processing module 10 applied to the above-described substrate processing system 1 will be described with reference to FIG. 3. FIG. 3 is a cross-sectional view schematically showing the processing module 10.

The processing module 10 according to the embodiment is configured as a plasma processing apparatus for performing plasma processing as substrate processing on the substrate W. In this case, the processing module 10 includes a gas supply part 16, a power supply 17, an exhaust system 18, or the like in addition to the processing chamber 11 and the substrate support 12 described above.

The processing chamber 11 is formed in a rectangular shape in plan view, and has a plasma processing space 10s therein. Further, the processing chamber 11 is grounded. The substrate support 12 is installed on a bottom wall 111 of the processing chamber 11 via an insulating member or the like (not shown).

The substrate support 12 includes a main body 121 having a perfect circular substrate supporting surface 121a that supports the substrate W, and the ring R that is placed on an annular ring supporting surface 121b that encircles the outer side of the substrate supporting surface 121a of the main body 121.

The main body 121 includes an electrostatic chuck 123 and a base 124 that are stacked in the vertical direction, and a protective member 125 that covers the outer peripheries of the electrostatic chuck 123 and the base 124. A part of the base 124 is a conductive member. The conductive member of the base 124 functions as a lower electrode. The electrostatic chuck 123 is disposed on the base 124. The upper surface of the electrostatic chuck 123 has the substrate supporting surface 121a and at least a part of the ring supporting surface 121b.

Further, the base 124 has therein a temperature controller (not shown) for controlling the temperature of the substrate W during plasma processing. The type of the temperature controller is not particularly limited, and may be a heater, a structure in which a flow path is formed therein so that a temperature control medium circulates through the flow path, or combination thereof.

The ring R is disposed around the outer edge of the substrate W to improve the uniformity of the plasma processing on the substrate W and to protect the electrostatic chuck 123 from the plasma. The ring R may be formed of one member, or may be formed by combining multiple members. At least one of one or multiple members is an edge ring or a focus ring disposed near the outer edge of the substrate W. When multiple members are combined, the ring R may be combination of multiple arc members divided along the circumferential direction, or combination of stacked multiple annular members with different diameters.

FIG. 4 is an enlarged cross-sectional view showing a state in which the ring R and the substrate W are placed on the substrate support 12. Hereinafter, the embodiment will be described using the ring R formed of one member as an example, as shown in FIG. 4.

The upper surface of the ring R has an outer annular surface Rout located radially outward from the outer edge of the substrate W, and an inner annular surface Rin located at the inner side of the outer annular surface Rout and facing the bottom surface of the substrate W. The inner annular surface Rin is lower than the outer annular surface Rout. In other words, the upper surface of the ring R has a stepped structure having an annular stepped inner circumferential surface RS between the outer annular surface Rout and the inner annular surface Rin.

For example, the inner annular surface Rin faces the bottom surface of the substrate W placed on the substrate supporting surface 121a in a non-contact manner. Therefore, the thickness of the portion having the inner annular surface Rin is pre-adjusted so that the inner annular surface Rin is positioned lower than the substrate supporting surface 121a when the ring R is placed on the ring supporting surface 121b. On the other hand, the thickness of the portion having the outer annular surface Rout is pre-adjusted so that the outer annular surface Rout is positioned at approximately the same level as the upper surface (front surface) of the substrate W placed on the substrate supporting surface 121a. The stepped inner circumferential surface RS has an inner diameter slightly greater than the outer diameter of the substrate W. Therefore, when the substrate W is placed, a small gap is generated between the outer edge of the substrate W and the stepped inner circumferential surface RS, thereby suppressing friction between the outer edge of the substrate W and the ring R.

The ring R is preferably made of a conductive material such as silicon (Si) or silicon carbide (SiC), or an insulating material such as quartz. The ring R made of the above material has hardness, and has a thermal expansion coefficient that can sufficiently suppress thermal expansion due to heat inputted from the substrate support 12 or plasma.

Referring back to FIG. 3, the processing chamber 11 of the processing module 10 has a gas introducing part that is connected to the gas supply part 16 and introduces at least one processing gas into the plasma processing space 10s of the processing chamber 11. For example, the gas introducing part includes the shower head 13 disposed in the processing chamber 11. The shower head 13 is disposed above the substrate support 12, and constitutes a part of the ceiling of the processing chamber 11. The plasma processing space 10s of the processing chamber 11 is defined by the shower head 13, a sidewall 112 of the processing chamber 11, and the substrate support 12.

The shower head 13 is configured to introduce at least one processing gas from the gas supply part 16 into the plasma processing space 10s. The shower head 13 has at least one gas supply port 13a, at least one gas diffusion space 13b, and multiple gas inlets 13c. The processing gas supplied to the gas supply port 13a passes through the gas diffusion space 13b and is introduced into the plasma processing space 10s from the multiple gas inlets 13c. Further, the shower head 13 includes a conductive member. The conductive member of the shower head 13 functions as an upper electrode. The gas introducing part may include, in addition to the shower head 13, one or multiple side gas injectors (SGI) attached to one or multiple openings formed in the sidewall 112.

The gas supply part 16 includes at least one gas source 161 and at least one flow rate controller 162. The gas supply part 16 supplies a processing gas from the gas source 161 to the shower head 13 via the flow rate controller 162. Each flow rate controller 162 may include, e.g., a mass flow controller or a pressure-controlled flow rate controller. Further, the gas supply part 16 may include one or more flow rate modulation devices that modulate the flow rate of at least one processing gas or causing it to pulsate.

The power supply 17 includes an RF power supply 171 coupled to the processing chamber 11 via at least one impedance matching circuit. The RF power supply 171 is configured to supply at least one RF signal (RF power), such as a source RF signal and a bias RF signal, to the conductive member of the substrate support 12 and/or the conductive member of the shower head 13. Accordingly, plasma is produced from at least one processing gas supplied to the plasma processing space 10s. Hence, the RF power supply 171 can function as at least a part of a plasma generator configured to generate plasma from one or more processing gases in the processing chamber 11. The RF power supply 171 can also generate a bias potential at the substrate W by supplying a bias RF signal to the conductive member of the substrate support 12, so that ion components in the plasma can be attracted to the substrate W.

In the embodiment, the RF power supply 171 includes a first RF generator 171a and a second RF generator 171b. The first RF generator 171a is coupled to the conductive member of the substrate support 12 and/or the conductive member of the shower head 13 via at least one impedance matching circuit, and is configured to generate a source RF signal (source RF power) for plasma generation. The source RF signal has a frequency within a range of 13 MHz to 150 MHz. The first RF generator 171a may be configured to generate a plurality of source RF signals having different frequencies. The generated one or multiple source RF signals are supplied to the conductive member of the substrate support 12 and/or the conductive member of the shower head 13. The second RF generator 171b is coupled to the conductive member of the substrate support 12 via at least one impedance matching circuit, and is configured to generate a bias RF signal (bias RF power). The bias RF signal has a frequency lower than that of the source RF signal. For example, the bias RF signal has a frequency within a range of 400 kHz to 13.56 MHz. The second RF generator 171b may be configured to generate a plurality of bias RF signals having different frequencies. The generated one or multiple bias RF signals are provided to the conductive member of the substrate support 12. In various embodiments, at least one of the source RF signal and the bias RF signal may pulsate.

Further, the power supply 17 may include a DC power supply 172 coupled to the processing chamber 11. The DC power supply 172 includes a first DC generator 172a and a second DC generator 172b. The first DC generator 172a is connected to the conductive member of the substrate support 12, and generates and applies a first DC signal to the conductive member. The first DC signal may be applied to an electrode in the electrostatic chuck 123. The second DC generator 172b is connected to the conductive member of the shower head 13, and generates and applies a second DC signal to the conductive member. At least one of the first DC signal or the second DC signal may pulsate. The first and second DC generators 172a and 172b may be provided in addition to the RF power supply 171, and the first DC generator 172a may be provided instead of the second RF generator 171b.

The exhaust system 18 has an exhaust line 181 connected to a gas exhaust port 10e disposed at the bottom wall 111 of the processing chamber 11, for example. The exhaust system 18 includes a pressure control valve for controlling the pressure in the plasma processing space 10s and a vacuum pump for conducting suction of a gas from the plasma processing space 10s, which are located at the intermediate portion of the exhaust line 181. The vacuum pump may include a turbo molecular pump, a dry pump, or combination thereof.

In the above substrate processing system 1, when the substrate W is transferred to the processing module 10 by the vacuum transfer device 22, the substrate W is placed on the substrate supporting surface 121a such that the center position 120 of the substrate supporting surface 121a coincides with the center position Wo of the substrate W, as shown in FIG. 4. In FIG. 4, a state in which the center position Wo of the substrate W is deviated from the center position 120 of the substrate supporting surface 121a of the substrate support 12 is shown in order to facilitate understanding of the present disclosure.

If the center position 120 of the substrate supporting surface 121a is deviated from the center position Wo of the substrate W, the in-plane uniformity of the plasma processing may be affected. Thus, the substrate processing system 1 performs a teaching method for teaching the transfer position of the substrate W in the processing module 10 to the controller 90 during installation of the system, maintenance, replacement of the ring R, or the like.

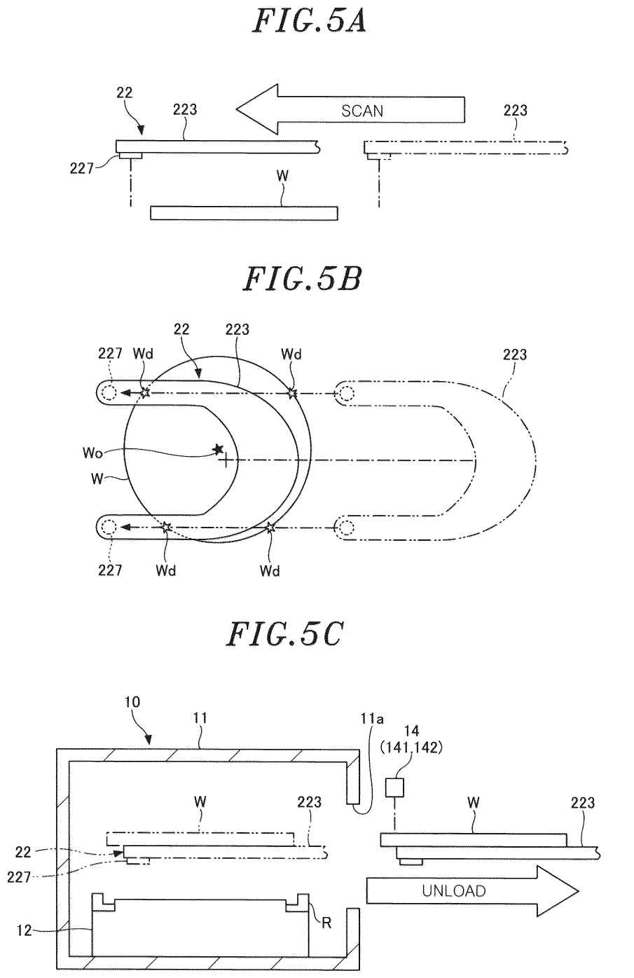

FIG. 5A is a side view explaining the principle of teaching the transfer position of the vacuum transfer device 22. FIG. 5B is a plan view explaining the principle of teaching the transfer position of the vacuum transfer device 22. FIG. 5C is a side view showing the operation of the processing module-side sensor 14 during calibration. As shown in FIGS. 5A and 5B, in the teaching method, the fork-side sensors 227 of the vacuum transfer device 22 are used to detect multiple positions of the outer edge of the substrate W, so that the center position Wo of the substrate W can be calculated from the multiple outer edge positions. Specifically, the controller 90 detects (scans) the substrate W with the fork-side sensors 227 while sliding the vacuum transfer device 22 horizontally and linearly at a position above the substrate W in the vertical direction. In this case, the linear movement of the vacuum transfer device 22 is controlled such that the reference position 2230 of the fork 223 passes through a preset design position.

The fork-side sensors 227 provided near the tip ends of the support plate portions 225 of the vacuum transfer device 22 detects the outer edge of the substrate W while passing through the position above the substrate W. When the fork-side sensors 227 pass through the position above the substrate W, the detectors 227a and 227b of the folk-side sensors 227 transmit timing of switching from a long distance to a short distance and timing of switching from a short distance to a long distance to the controller 90. Further, the controller 90 recognizes the position of the fork 223, i.e., the positions (three-dimensional coordinates) of the detectors 227a and 227b, based on the operations of the arms 222 of the vacuum transfer device 22 during scanning of the vacuum transfer device 22. The controller 90 can recognize four locations Wd (see white stars in FIG. 5B) on the outer edge of the substrate W by associating the timing of the detection information of the fork-side sensors 227 with the recognized positions of the detectors 227a and 227b.

The fork-side sensors 227 do not necessarily detect the outer edge of the substrate W or the inner edge of the ring R, which is the transfer object, based on the displacement amount detected by an optical displacement sensor. For example, the fork-side sensors 227 may detect the edge of the transfer object by obtaining a transition point in the intensity of received light (intensity of light irradiated and reflected from the fork-side sensors 227 to a target). In brief, in the teaching method, the edge of the transfer object can be detected based on the transition point in the measurement value of the sensor applied to the fork-side sensors 227 (e.g., the transition point in the intensity of received light).

The controller 90 calculates the center position Wo (see the black star in FIG. 5B) of the substrate W using the positions of the four detected locations Wd. For example, the controller 90 can calculate normal lines extending radially inward from the four detected locations Wd, and can calculate the point where the normal lines intersect with each other as the center position of the substrate W.

Further, the controller 90 may teach the center position 120 of the substrate support 12 as the transfer position in order to place the substrate W on the substrate support 12. For example, the center positions 120 and Wo of the substrate W are calculated by detecting the outer edge of the substrate support 12 and the outer edge of the substrate W by sliding the fork 223 above the substrate W placed on the substrate support 12. The controller 90 can recognize the transfer position where the center position 120 and the center position Wo coincide with each other by obtaining the deviation amount and the deviation direction between the center position 120 of the substrate support 12 and the center position Wo of the substrate W.

Further, in the substrate processing system 1, the processing module-side sensor 14 can be calibrated using the substrate W that is placed in a state where the center position Wo thereof coincides with the center position 120 of the substrate support 12. Specifically, the controller 90 controls the vacuum transfer device 22 to receive the substrate W placed on the substrate support 12 as shown in FIG. 5C, and controls the vacuum transfer device 22 to retract so that the outer edge of the substrate W is detected by the detectors 141 and 142 when the substrate W passes through the processing module-side sensor 14. When the substrate W whose center position Wo coincides with the center position 120 of the substrate support 12 passes, the center position Wo of the substrate W passes through the gap between the detectors 141 and 142 of the processing module-side sensor 14 at the timing specified by the speed of the vacuum transfer device 22. In other words, the controller 90 can recognize the position of the outer edge of the substrate W accurately placed on the substrate support 12 based on the detection results of the detectors 141 and 142, and can set it as the reference coordinate position at the time when the substrate W supported by the vacuum transfer device 22 passes during an actual operation. In the embodiment, the operation until the calibration of the processing module-side sensor 14 in the substrate processing system 1, which includes the teaching method, is referred to as “calibration method.”

However, as shown in FIG. 4, the processing module 10 for performing plasma processing has the substrate supporting surface 121a with an outer diameter smaller than that of the substrate W so that the ring R can be placed thereon. In this case, the outer edge of the substrate supporting surface 121a is covered by the substrate W placed on the substrate support 12. Therefore, in a conventional method in which the outer edge of the substrate support 12 and the outer edge of the substrate W are simultaneously scanned by the fork-side sensors 227, the recognition accuracy of the center position 120 of the substrate support 12 decreases.

Therefore, in the calibration method according to the embodiment, the position of the substrate W with respect to the substrate support 12 is determined based on the positional relationship between the substrate support 12 and the ring R, and the positional relationship between the ring R and the substrate W. Then, the processing module-side sensor 14 is calibrated. Hereinafter, this method will be described in detail.

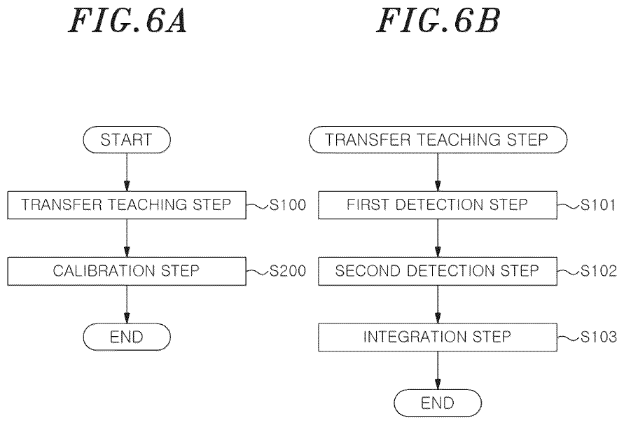

FIG. 6A is a flowchart showing the calibration method according to the embodiment. FIG. 6B is a flowchart showing a transfer teaching step of the calibration method. As shown in FIG. 6A, in the calibration method according to the embodiment, a transfer teaching step (step S100) and a calibration step (step S200) are performed in that order under the control of the controller 90. In the transfer teaching step, the teaching of a transfer position for placing the substrate W on the substrate support 12 of the processing module 10 is performed. In the calibration step, the processing module-side sensor 14 is calibrated using the substrate W placed on the substrate support 12 by the transfer teaching step.

As shown in FIG. 6B, in the transfer teaching step, a first detection step (step S101), a second detection step (step S102), and an integration step (step S103) are performed under the control of the controller 90. In the first detection step, the deviation state between the substrate support 12 and the ring R is recognized by performing the scanning using the fork-side sensors 227 of the vacuum transfer device 22 in a state where the ring R is placed on the substrate support 12. In the second detection step, the deviation state between the ring R and the substrate W is recognized by performing the scanning using the fork-side sensors 227 of the vacuum transfer device 22 in a state where the ring R and the substrate W are placed on the substrate support 12. In the integration step, the deviation state of the substrate W with respect to the substrate support 12 is recognized based on the information from the first detection step and the information from the second detection step.

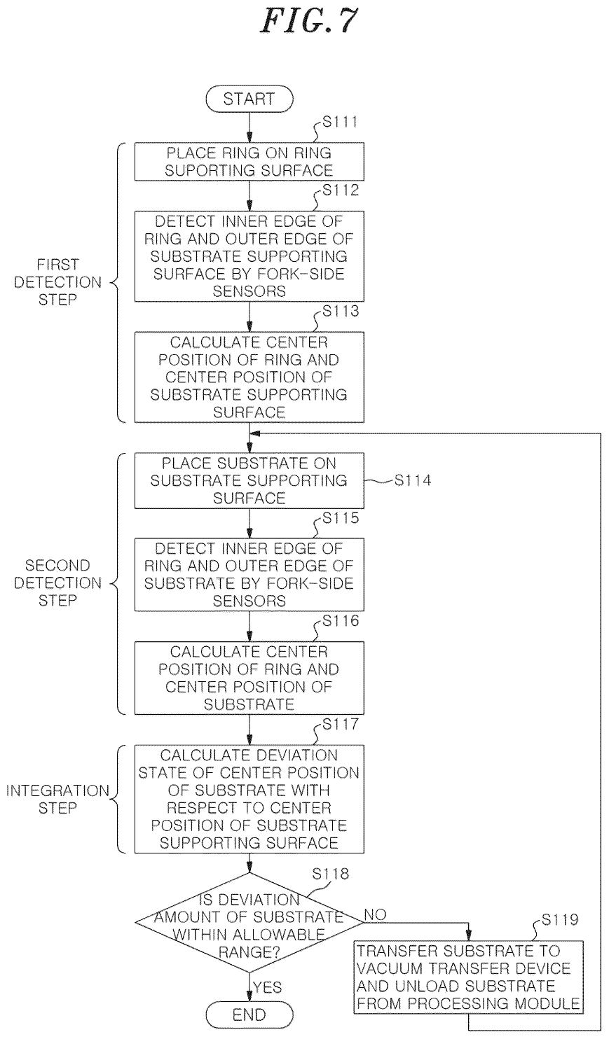

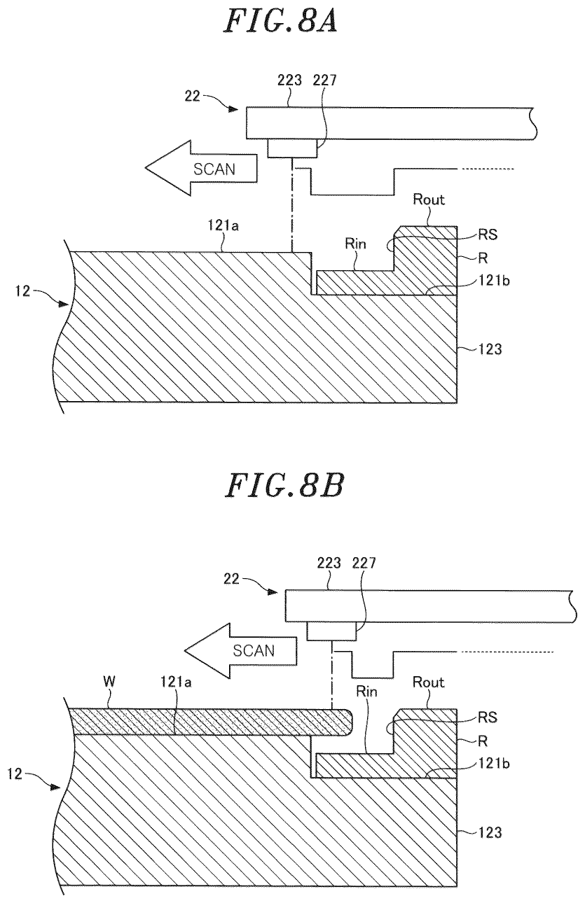

More specifically, in the transfer teaching step, steps S111 to S118 shown in FIG. 7 are executed sequentially. FIG. 7 is a flowchart specifically showing the operations of individual components in the transfer teaching step. FIG. 8A is a cross-sectional view showing the detection operation of the substrate support 12 and the ring R in the first detection step. FIG. 8B is a cross-sectional view showing the detection operation of the ring R and the substrate W in the second detection step.

The controller 90 starts the first detection step of the transfer teaching step (see step S101 in FIG. 6B). First, the controller 90 places the ring R on the ring supporting surface 121b of the substrate support 12 (step S111). In the case where the ring R is loaded into the processing module 10 by the vacuum transfer device 22, the ring R is placed on the substrate support 12 by the transfer of the vacuum transfer device 22. For example, the controller 90 controls the movement of the vacuum transfer device 22 such that the ring R is transferred to a transfer position that is predetermined by initial setting.

Alternatively, in the case where the ring R is loaded into the processing module 10 by an operator, the controller 90 controls the inner atmosphere of the processing chamber 11 to an atmospheric atmosphere, and notifies the operator to place the ring R. Accordingly, the operator opens the lid of the processing chamber 11 and places the ring R on the exposed substrate support 12. In this case, it is preferable that the operator accurately positions the ring R with respect to the substrate support 12 by using a positioning jig (not shown) corresponding to the substrate support 12 and the ring R.

Next, the controller 90 slides the fork 223 to pass through a position above the substrate support 12 on which the ring R is placed, and controls the fork-side sensors 227 to detect the inner edge of the ring R and the outer edge of the substrate supporting surface 121a (step S112).

Specifically, as shown in FIG. 8A, when the fork 223 slides, the fork-side sensors 227 detect a change in the level of the upper surface of the ring R at the inner edge shifted from the outer annular surface Rout to the stepped inner circumferential surface RS. Further, as the fork 223 slides, the fork-side sensors 227 detect the change in the level of the upper surface of the substrate support 12 at the outer edge shifted from the ring supporting surface 121b to the substrate supporting surface 121a. Accordingly, the fork-side sensors 227 can obtain four detection positions at the inner edge of the ring R, and can obtain four detection positions at the outer edge of the substrate supporting surface 121a.

Then, the controller 90 calculates the center position Ro of the ring R by using the detection positions at the inner edge of the ring R, and calculates the center position 120 of the substrate supporting surface 121a by using the detection positions at the outer edge of the substrate supporting surface 121a (step S103). If the center position Ro of the ring R does not coincide with the center position 120 of the substrate support 12, the ring R is deviated when it is placed on the substrate support 12. However, if the deviation amount and the deviation direction of the ring R with respect to the substrate support 12 are already obtained, it is not necessary to correct the deviation of the ring R. This is because the deviation of the substrate W with respect to the substrate supporting surface 121a can be recognized by performing calculation in consideration of the deviation amount and the deviation direction of the ring R in the subsequent steps. If the deviation amount of the ring R is large, it is preferable to perform a process of placing the ring R again.

Next, the controller 90 proceeds from the first detection step to the second detection step (see step S102 in FIG. 6B). The controller 90 controls the vacuum transfer device 22 to transfer the substrate W and place the substrate W on the substrate supporting surface 121a of the substrate support 12 on which the ring R is placed (step S114). In this case, the controller 90 can transfer the substrate W using the previously calculated center position 120 of the substrate supporting surface 121a as a temporary transfer position.

Next, the controller 90 slides the fork 223 to pass through a position above the substrate support 12 on which the substrate W is placed, and detects the inner edge of the ring R and the outer edge of the substrate W using the fork-side sensors 227 (step S115).

Specifically, as shown in FIG. 8B, when the fork 223 slides, the fork-side sensors 227 detect a change in the level of the surface of the ring R at a position where the outer annular surface Rout shifted to the stepped inner circumferential surface RS. Further, as the fork 223 slides, the fork-side sensors 227 detect a change in the level of the surface of the substrate W at a position where the inner annular surface Rin shifted to the outer edge of the substrate W. Accordingly, the fork-side sensors 227 can obtain four detection positions at the inner edge of the ring R and four detection positions at the outer edge of the substrate W.

Then, the controller 90 calculates the center position Ro of the ring R by using the detection positions on the inner edge of the ring R, and calculates the center position Wo of the substrate W by using the detection positions on the outer edge of the substrate W (step S116). Here, if the center position Wo of the substrate W does not coincide with the center position Ro of the ring R, the substrate W is deviated when it is placed on the substrate support 12.

Then, the controller 90 proceeds from the second detection step to an integration step in order to recognize the deviation of the center position Wo of the substrate W with respect to the center position 120 of the substrate supporting surface 121a (see step S103 in FIG. 6B). In the integration step, the controller 90 calculates the deviation state of the center position Wo of the substrate W with respect to the center position 120 of the substrate supporting surface 121a (step S117). In other words, the controller 90 can recognize the deviation amount and the deviation direction of the center position 120 of the substrate supporting surface 121a based on the center position Ro of the ring R placed on the substrate support 12, and can also recognize the deviation amount and the deviation direction of the center position Wo of the substrate W. Therefore, the controller 90 can accurately recognize the deviation state of the center position Wo of the substrate W with respect to the center position 120 of the substrate supporting surface 121a based on the positional relationship between the substrate support 12 and the ring R and the positional relationship between the ring R and the substrate W.

After the integration step, the controller 90 determines whether the deviation amount between the center position 120 of the substrate supporting surface 121a and the center position Wo of the substrate W is within an allowable range (step S118). If the deviation amount of the center position Wo of the substrate W is within the allowable range (step S118: YES), it is determined that the substrate W is accurately placed on the substrate supporting surface 121a. Therefore, the controller 90 ends the transfer teaching step. On the other hand, if the deviation amount of the center position Wo of the substrate W is not within the allowable range (step S118: NO), the controller 90 executes step S118.

In step S119, the controller 90 transfers the substrate W from the substrate support 12 to the vacuum transfer device 22, and unloads the substrate W from the processing module 10. Then, the processing returns to step S114, and the controller 90 controls the vacuum transfer device 22 to place the substrate W on the substrate supporting surface 121a again. In this case, the controller 90 corrects the transfer position of the vacuum transfer device 22 based on the deviation state (the deviation amount and the deviation direction) of the substrate W calculated in step S117, and moves the vacuum transfer device 22. As described above, in the substrate processing system 1, steps S114 to S118 can be repeated such that the center position Wo of the substrate W substantially coincides with the center position 120 of the substrate supporting surface 121a (such that they are within the allowable range).

In the calibration method, by performing the transfer teaching step, the substrate W can be placed such that the center position Wo of the substrate W coincides with the center position 120 of the substrate supporting surface 121a. Therefore, referring back to FIG. 6A, in the calibration method, in the calibration step subsequent to the transfer teaching step, it is possible to calibrate the processing module-side sensor 14 using the substrate W accurately placed on the substrate support 12.

In the calibration step, as described above, the controller 90 controls the vacuum transfer device 22 to receive the substrate W placed on the substrate support 12, and retracts the vacuum transfer device 22 so that the substrate W passes through a position below the processing module-side sensor 14 (see FIG. 5C). Accordingly, the detectors 141 and 142 of the processing module-side sensor 14 detect the outer edge of the substrate W placed with high precision. The controller 90 can calibrate the position of the substrate W to be applied during actual operation based on the detection information detected by the detectors 141 and 142.

As described above, in the substrate processing system 1 and the calibration method, the transfer position of the substrate W with respect to the substrate support 12 can be appropriately obtained even when the outer diameter of the substrate supporting surface 121a is smaller than the outer diameter of the substrate W. Accordingly, the substrate W can be accurately placed on the substrate support 12, and the calibration accuracy of the processing module-side sensor 14 can be improved. Further, in the substrate processing system 1, even during an operation in which substrate processing is performed on the substrate W, the substrate W can be accurately placed on the substrate support 12 by using the detection information of the calibrated processing module-side sensor 14. As a result, the improvement of the in-plane uniformity of the substrate processing on the substrate W can be expected. Further, the substrate processing system 1 does not necessarily perform the transfer teaching step during installation or maintenance of the device, and can recognize the deviation state of the substrate W and the ring R with respect to the center position 120 of the substrate support 12 by detecting the positions of the substrate W and the ring R even during an operation. Hence, the substrate processing system 1 can require maintenance or the like depending on the deviation state.

The calibration method and the substrate processing system 1 of the present disclosure are not limited to the above embodiment, and may be variously modified. For example, in the above embodiment, the case of teaching the transfer position of the vacuum transfer device 22 in the processing module 10 has been described. However, the present disclosure is not limited thereto, and the substrate processing system 1 may have a similar configuration even in the case of teaching the transfer position of the atmospheric transfer device 42.

In the transfer teaching step of the calibration method, it is not necessary to perform the first detection step, the second detection step, and the integration step. For example, it is possible to employ a method in which a teaching substrate having a diameter smaller than the diameter of the substrate supporting surface 121a is placed, as a substrate W for teaching a transfer position, on the substrate supporting surface 121a, and the outer edge of the substrate and the outer edge of the substrate are detected simultaneously by the fork-side sensors 227.

The calibration method according to the embodiment is not necessarily performed for the processing module-side sensor 14 corresponding to the processing module 10 where the ring R and the substrate W are placed on the substrate support 12. For example, even for the processing module 10 where the ring R is not placed on the substrate support 12, the transfer teaching step for placing the substrate W such that the center position Wo thereof coincides with the center position Wo of the substrate support 12 may be executed and, then, the calibration step may be executed. In that case as well, the processing module-side sensor 14 can be calibrated with high accuracy.

Further, in the calibration method, if the substrate W can be placed such that the center position Wo of the substrate W coincides with the center position 120 of the substrate support 12 (or is located within the allowable range from the center position 120 of the substrate support 12), the processing module-side sensor 14 can be calibrated and, thus, the transfer teaching step may not be performed. For example, if an operator uses a positioning jig to place the substrate W such that the center of the substrate support 12 and the center of the substrate W are within the tolerance range, the calibration step may be started immediately after the substrate W is placed.

Hereinafter, the technical ideas and effects of the present disclosure according to the above embodiment will be described.

A first aspect of the present disclosure provides a calibration method for calibrating a sensor in a system including a transfer device (the vacuum transfer device 22) for transferring a transfer object (the substrate W), and a sensor (the processing module-side sensor 14) for detecting the object to recognize a position of the object that is being transferred by the transfer device, the method including: (A) placing the object on a support part (the substrate support 12) capable of supporting the object such that a center position of the object is located within an allowable range from a center position of the support part; and (B) after said (A), holding and transferring the object placed on the support part by the transfer device, detecting the object that is being transferred by the sensor, and calibrating the position of the object detected by the sensor.

In accordance with the above, in the calibration method, the transfer object (the substrate W) whose center position coincides with the center position of the support part (the substrate support 12) is transferred by the transfer device (the vacuum transfer device 22). Then, in the calibration method, the transfer object that is being transferred by the transfer device is detected by the sensor (the processing module-side sensor 14), so that the sensor can be calibrated accurately. As a result, the system can accurately detect the position of the transfer object by the sensor during an operation of actually transferring the object, thereby improving the transfer accuracy of the transfer object.

Further, the transfer object is the substrate W. The support part (the substrate support 12) supports the substrate W and the ring R disposed at the outer side of the outer edge of the substrate W, and the diameter of the substrate supporting surface 121a that supports the substrate W of the support part is smaller than the diameter of the substrate W. Accordingly, the calibration method can be performed even for the support part that supports the substrate W and the ring R.

Said (A) includes: (A-1) detecting a deviation state between the ring R placed on the support part (the substrate support 12) and the substrate supporting surface 121a; (A-2) detecting a deviation state between the ring R placed on the support part and the substrate placed on the substrate supporting surface 121a; and (A-3) recognizing a deviation state of the substrate with respect to the substrate supporting surface 121a based on the deviation state between the ring R and the substrate supporting surface 121a and the deviation state between the ring R and the substrate W. Accordingly, in the calibration method, it is possible to accurately recognize the deviation of the substrate W with respect to the substrate supporting surface 121a.

Further, in said (A-2), the substrate is transferred by the transfer device and placed on the substrate supporting surface. After said (A-3), it is determined whether or not a deviation amount between a center position 120 of the substrate supporting surface 121a and a center position Wo of the substrate W is within the allowable range. When the deviation amount is within the allowable range, and the method proceeds to said (B). On the other hand, when the deviation amount is not within the allowable range, the substrate is separated from the support part (the substrate support 12) by the transfer device and said (A-2) and (A-3) are performed again. Accordingly, in the calibration method, said (B) can be performed after the center position Wo of the substrate W substantially coincides with the center position 120 of the support part.

Further, in said (A-1), the transfer device (the vacuum transfer device 22) is moved above the ring R placed on the support part (the substrate support 12), and an inner edge of the ring R and an outer edge of the substrate supporting surface 121a are detected by a transfer device-side sensor of the transfer device (the fork-side sensors 227). In said (A-2), the transfer device is moved above the ring R and the substrate W placed on the support part, and the inner edge of the ring R and an outer edge of the substrate W are detected by the transfer device-side sensor of the transfer device. Hence, in the calibration method, it is possible to simply obtain the deviation state of the substrate supporting surface 121a and the deviation state of the substrate W with respect to the ring R.

Further, the transfer device (the vacuum transfer device 22) includes the fork 223 on which the substrate W is placed, and the plurality of arms 222 for moving the fork 223. The transfer device side sensor (the fork-side sensors 227) is a displacement sensor disposed at the fork 223 and measures a distance to an opposing object. Accordingly, in the calibration method, it is possible to stably detect the substrate supporting surface 121a, the ring R, and the substrate W using the transfer device side sensor.

Further, the transfer device side sensor (the fork-side sensors 227) has the pair of detectors 227a and 227b at the tip ends of the fork 223. The pair of detectors 227a and 227b are arranged at an interval narrower than the diameter of the substrate W. Accordingly, in the calibration method, it is possible to reliably detect the outer edge of the substrate W using the transfer device side sensor, and also possible to calculate the center position Wo thereof.

Further, the sensor (the processing module-side sensor 14) has the pair of detectors 141 and 142 that are disposed near the opening of the processing module 10 having the support part (the substrate support 12), and are arranged in parallel to the opening. In the calibration method, the sensor can reliably detect the outer edge of the substrate W, which makes it possible to calculate the center position Wo thereof.

A second aspect of the present disclosure provides the substrate processing system 1 including: the transfer device (the vacuum transfer device 22) configured to transfer the transfer object (the substrate W); the support part (the substrate support 12) configured to support the transfer object; the sensor (the processing module-side sensor 14) configured to detect the transfer object to recognize a position of the transfer object that is being transferred by the transfer device; and the controller 90 configured to controls the transfer device. The controller 90 controls: (A) placing the transfer object on the support part such that a center position of the object is located within an allowable range from a center position of the support part; and (B) after said (A), holding and transferring the transfer object placed on the support part by the transfer device, detecting the transfer object that is being transferred by the sensor, and calibrating a position of the transfer object detected by the sensor. Even in this case, the substrate processing system 1 can improve the transfer accuracy of the transfer object.

It should be noted that the calibration method and the plasma processing system 1 according to the embodiments of the present disclosure are illustrative in all respects and are not restrictive. The above-described embodiments may be modified and improved in various forms without departing from the scope of the appended claims and the gist thereof. The above-described embodiment may include other configurations without contradicting each other and may be combined without contradicting each other.

The processing module 10 of the present disclosure may be applied to any of the following types of devices, such as an atomic layer deposition (ALD) device, capacitively coupled plasma (CCP), inductively coupled plasma (ICP), a radial line slot antenna (RLSA), electron cyclotron resonance plasma (ECR), and helicon wave plasma (HWP).

1. A calibration method for calibrating a sensor in a system including a transfer device for transferring an object, and the sensor for detecting the object to recognize a position of the object that is being transferred by the transfer device, the method comprising:
(A) placing the object on a support part configured to support the object such that a center position of the object is located within an allowable range from a center position of the support part; and
(B) after said (A), holding and transferring the object placed on the support part by the transfer device, detecting the object that is being transferred by the sensor, and calibrating the position of the object detected by the sensor.

2. The calibration method of claim 1, wherein the object is a substrate,
the support part supports the substrate and a ring disposed outside the outer edge of the substrate, and
a diameter of a substrate supporting surface of the support part that supports the substrate is smaller than a diameter of the substrate.

3. The calibration method of claim 2, wherein said (A) includes:
(A-1) detecting a deviation state between the ring placed on the support part and the substrate supporting surface;
(A-2) detecting a deviation state between the ring placed on the support part and the substrate placed on the substrate supporting surface; and
(A-3) recognizing a deviation state of the substrate with respect to the substrate supporting surface based on the deviation state between the ring and the substrate supporting surface and the deviation state between the ring and the substrate.

4. The calibration method of claim 3, wherein in said (A-2), the substrate is transferred by the transfer device and placed on the substrate supporting surface,
after said (A-3), it is determined whether or not a deviation amount between a center position of the substrate supporting surface and a center position of the substrate is within the allowable range, and the method proceeds to said (B) when the deviation amount is within the allowable range, and
the substrate is separated from the support part by the transfer device and said (A-2) and (A-3) are performed again when the deviation amount is not within the allowable range.

5. The calibration method of claim 3, wherein in said (A-1), the transfer device is moved above the ring placed on the support part, and an inner edge of the ring and an outer edge of the substrate supporting surface are detected by a transfer device-side sensor of the transfer device, and
in said (A-2), the inner edge of the ring and an outer edge of the substrate are detected by the transfer device-side sensor of the transfer device by moving the transfer device above the ring and the substrate placed on the support part.

6. The calibration method of claim 5, wherein the transfer device includes a fork on which the substrate is placed and a plurality of arms for moving the fork, and
the transfer device-side sensor is a displacement sensor disposed at the fork and configured to measure a distance to an opposing object.

7. The calibration method of claim 6, wherein the transfer device-side sensor has a pair of detectors at the tip ends of the fork, and the pair of detectors are arranged at an interval smaller than a diameter of the substrate.

8. The calibration method of claim 1, wherein the sensor is disposed near an opening of a processing module having the support part, and has a pair of detectors arranged in parallel to the opening.

9. A substrate processing system comprising:
a transfer device configured to transfer a transfer object;
a support part configured to support the transfer object;
a sensor configured to detect the transfer object to recognize a position of the transfer object that is being transferred by the transfer device; and
a controller configured to controls the transfer device,
wherein the controller controls:
(A) placing the transfer object on the support part such that a center position of the object is located within an allowable range from a center position of the support part; and
(B) after said (A), holding and transferring the transfer object placed on the support part by the transfer device, detecting the transfer object that is being transferred by the sensor, and calibrating a position of the transfer object detected by the sensor.
